(19) United States
(12) Patent Application Publication
(10) Pub. No.: US 2016/0080004 A1
(43) Pub. Date: Mar. 17, 2016

(54) MEMORY CONTROLLER AND DECODING METHOD

(71) Applicant: Kabushiki Kaisha Toshiba, Minato-ku (JP)

(72) Inventors: Ryo YAMAKI, Yokohama (JP); Daisuke Fujiwara, Yokohama (JP); Daiki Watanabe, Yokohama (JP)

(73) Assignee: Kabushiki Kaisha Toshiba, Minato-ku (JP)

(21) Appl. No.: 14/656,037

(22) Filed: Mar. 12, 2015

Related U.S. Application Data
(60) Provisional application No. 62/048,987, filed on Sep. 11, 2014.

(51) Int. Cl. H03M 13/45; G11C 29/52; G06F 11/10

(52) U.S. Cl. CPC H03M 13/458; G06F 11/1068; G11C 29/52

(57) ABSTRACT

According to an embodiment, a memory controller controls a non-volatile memory that stores a codeword. The memory controller includes a SISO decoder that performs SISO decoding based on the codeword read out as a set of soft decision values from the non-volatile memory, and outputs a posteriori information; a hard decision processor that performs hard decision on the a posteriori information and calculates a set of hard decision values of the codeword; and a HIHO decoder that performs HIHO decoding by using the hard decision values.

### CROSS-REFERENCE TO RELATED APPLICATIONS

This application is based upon and claims the benefit of priority from U.S. Provisional Application No. 62/048,987, filed on Sep. 11, 2014; the entire contents of which are incorporated herein by reference.

### FIELD

Embodiments described herein relate generally to a memory controller and a decoding method.

### BACKGROUND

Generally, in a storage device, data is stored while being applied with error correction coding in order that the data to be stored is protected. Methods of decoding a codeword, on which error correction coding has been performed, include HIHO (hard-input hard-output) decoding and SISO (soft-input soft-output) decoding. SISO decoding has higher error correction performance than that of HIHO decoding, but takes a longer processing time.

### BRIEF DESCRIPTION OF THE DRAWINGS

FIG. 1 is a block diagram illustrating an exemplary configuration of a storage device according to a first embodiment;

FIG. 2 is a diagram illustrating an exemplary configuration of a product codeword of the first embodiment;

FIG. 3 is a diagram illustrating an exemplary configuration of a decoder of the first embodiment;

FIG. 4 is a flowchart illustrating an example of a reading procedure of the first embodiment;

FIG. 5 is a diagram for explaining soft bit read;

FIG. 6 is a diagram illustrating an exemplary LLR table;

FIG. 7 is a flowchart illustrating an exemplary procedure of SISO-HIHO decoding of the first embodiment;

FIG. 8 is a flowchart illustrating an exemplary procedure of SISO-HIHO decoding of a second embodiment; and

FIG. 9 is a flowchart illustrating an exemplary procedure of SISO-HIHO decoding of a third embodiment.

### DETAILED DESCRIPTION

According to the embodiments described herein, a memory controller, which controls a non-volatile memory configured to store codewords, includes a SISO decoder which performs SISO decoding based on the received word corresponding to the codeword read as a set of soft decision values from the non-volatile memory and outputs a posteriori information. The memory controller also includes a hard decision processor which performs hard decision on a posteriori information and calculates a hard decision value for each bit in the codeword, and a HIHO decoder which performs HIHO decoding by using the hard decision value for each bit in the codeword.

Hereinafter, a memory controller and decoding methods according to the embodiments will be described in detail with reference to the accompanying drawings. It should be noted that the present invention is not limited by those embodiments.

### First Embodiment

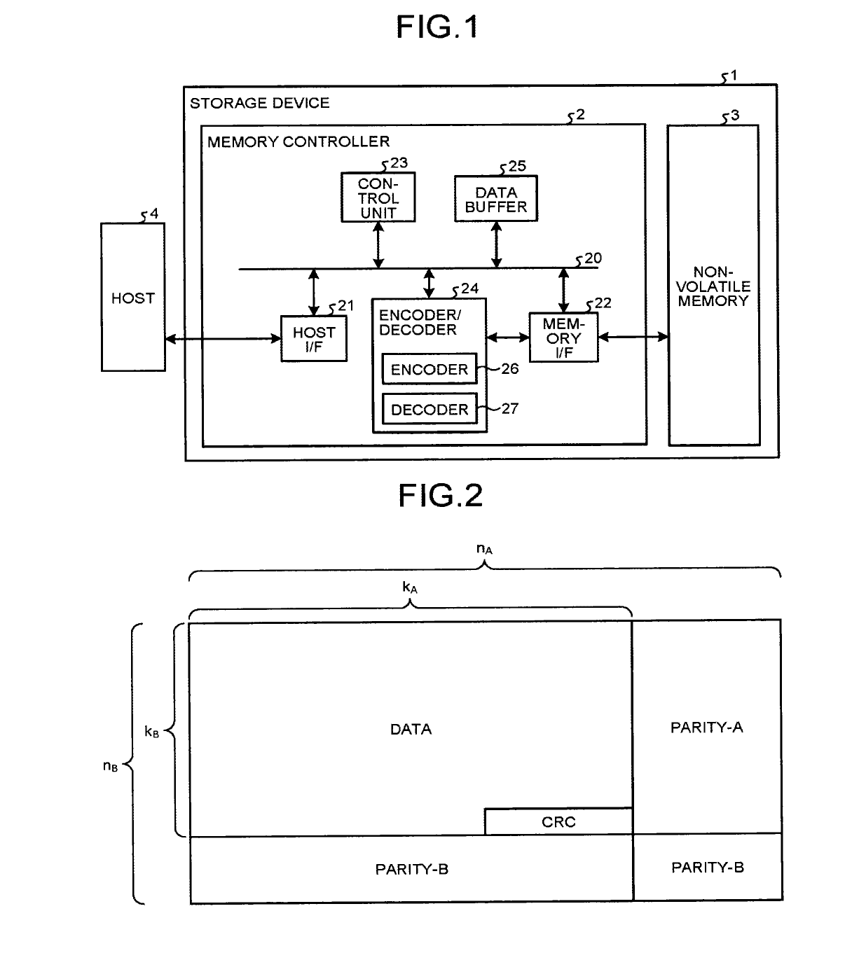

FIG. 1 is a block diagram illustrating an exemplary configuration of a storage device according to a first embodiment. A storage device 1 of the present embodiment includes a memory controller 2 and a non-volatile memory 3. The storage device 1 is connectable with a host 4. FIG. 1 illustrates a state where the storage device 1 is connected with the host 4. The host 4 is an electronic device such as a personal computer, a mobile terminal, or the like.

The non-volatile memory 3 is a non-volatile memory configured to store data in a non-volatile manner, which is a NAND memory, for example. It should be noted that while an example of using a NAND memory as the non-volatile memory 3 is described herein, a storage unit other than the NAND memory such as a three-dimensional structural flash memory, a ReRAM (Resistance Random Access Memory), a FeRAM (Ferroelectric Random Access Memory), or the like may be used as the non-volatile memory 3. Further, while an example of using a semiconductor memory as a storage unit is described herein, it is possible to apply error correction processing of the present embodiment to a storage device using a storage unit other than a semiconductor memory.

The storage device 1 may be a memory card in which the memory controller 2 and the non-volatile memory 3 are configured as one package, an SSD (Solid State Drive), or the like.

The memory controller 2 controls writing to the non-volatile memory 3 in accordance with a write command (request) from the host 4. The memory controller 2 also controls reading from the non-volatile memory 3 in accordance with a read command from the host 4. The memory controller 2 includes a host I/F (host interface) 21, a memory I/F (memory interface) 22, a control unit 23, an encoder/decoder 24, and a data buffer 25. The host I/F 21, the memory I/F 22, the control unit 23, the encoder/decoder 24 and the data buffer 25 are connected via an internal bus 20.

The host I/F 21 performs processing adhering to the interface standard with the host 4, and outputs commands, user data, and the like, received from the host 4, to the internal bus 20. The host I/F 21 also transmits user data read from the non-volatile memory 3, responses from the control unit 23, and the like, to the host 4. It should be noted that in the present embodiment, data to be written into the non-volatile memory 3 according to a request from the host 4 is called used data.

The memory I/F 22 performs write processing to the non-volatile memory 3 based on an instruction from the control unit 23. The memory I/F 22 also performs read processing from the non-volatile memory 3 based on an instruction from the control unit 23.

The control unit 23 is a control unit which generally controls the respective components of the storage device 1. When the control unit 23 receives a command from the host 4 via the host I/F 21, the control unit 23 performs control in accordance with the command. For example, the control unit 23 instructs the memory I/F 22 to write user data and parity into the non-volatile memory 3 in accordance with a command from the host 4. Further, the control unit 23 instructs the memory I/F 22 to read user data and parity from the non-volatile memory 3 in accordance with a command from the host 4.

Further, when the control unit 23 receives a write request from the host 4, the control unit 23 determines a storage area (memory area) on the non-volatile memory 3, with respect to user data accumulated in the data buffer 25. This means that the control unit 23 determines a writing destination of the user data and manages the writing destination. A correspondence between the logical address of the user data received from the host 4 and the physical address indicating the storage area on the non-volatile memory 3 in which the user data is stored is stored as an address conversion table.

Further, when the control unit 23 receives a read request from the host 4, the control unit 23 converts the logical address, designated by the read request, to the physical address using the address conversion table, and instructs the memory I/F 22 to read from the physical address.

In the NAND memory of the NAND memory, reading and writing are performed in data units called pages, and erasure is performed in data units called blocks, generally. In the present embodiment, memory cells connected with the same word line are called a memory cell group. If a memory cell is a single level cell (SLC), one memory cell group corresponds to one page. If a memory cell is a multi-level cell (MLC), one memory cell group corresponds to a plurality of pages. Each memory cell is connected with a word line, and is also connected with a bit line. Each memory cell is identifiable with an address identifying a word line and an address identifying a bit line.

The data buffer 25 temporarily stores user data, received from the host 4 by the memory controller 2, until it is stored in the non-volatile memory 3. The data buffer 25 also temporarily stores user data, read from the non-volatile memory 3, until it is transmitted to the host 4. The data buffer 25 is configured of a general-purpose memory such as an SRAM (Static Random Access Memory), a DRAM (Dynamic Random Access Memory), or the like, for example.

User data, transmitted from the host 4, is transferred to the internal bus 20 and is stored in the data buffer 25. The encoder/decoder 24 encodes data to be stored in the non-volatile memory 3 to thereby generate a codeword. The encoder/decoder 24 includes an encoder 26 and a decoder 27. The details of encoding and decoding of the present embodiment will be described below.

Generally, in a storage device, a method of protecting data to be stored by using error correction codes has been known. As specific error correction codes, codes having a plurality of constraint conditions such as product codes configured by combining block codes, staircase codes, braided codes, and the like for example, may be used. In the case of using those codes, HIHO decoding is performed generally for decoding. On the other hand, in the case of using those codes, it is also possible to perform SISO decoding. SISO decoding has higher error correction performance than that of HIHO decoding, but takes a longer processing time. In the present embodiment, when SISO decoding is performed, it is combined with HIHO decoding so as to reduce the processing time.

Hereinafter, encoding and decoding of the present embodiment will be described. Here, while description will be given on product codeword generated by combining two or more dimensional block codes, the decoding method of the present embodiment is applicable to any codes without limiting to product codeword, provided that HIHO decoding is possible and that the codes have a plurality of constraint conditions. For example, the decoding method of the present embodiment is applicable to staircase codes, braided codes, and the like.

Next, write processing of the present embodiment will be described. When the control unit 23 performs writing to the non-volatile memory 3, the control unit 23 instructs the encoder 26 to encode data, determines a storage location (storage address) of a codeword in the non-volatile memory 3, and makes an instruction to the memory I/F 22. Based on the instruction from the control unit 23, the encoder 26 encodes the data on the data buffer 25 and generates a codeword. The memory I/F 22 performs control to store the codeword on the storage location on the non-volatile memory 3 instructed by the control unit 23.

The encoder 26 generates a product codeword, for example. FIG. 2 is a diagram illustrating an exemplary configuration of a product codeword of the present embodiment. FIG. 2 illustrates an example using a two-dimensional product codeword. In the example of FIG. 2, the product codeword is configured of a two-dimensional codeword group having a first dimension (horizontal direction) and a second dimension (vertical direction). Data of FIG. 2 is user data. It should be noted that in the case of protecting control data or the like, other than the user data, to be used inside the controller 2 by the same product codeword as the user data, the data is control data or the like protected by the product codeword. The code length of each codeword of the first dimension is n_{A} bits, the information bits of each codeword of the first dimension are k_{A} bits, and the redundant bits of each codeword of the first dimension, namely, parity-A, are (n_{A}−k_{A}) bits. The code length of each codeword of the second dimension is n_{B} bits, the information bits of each codeword of the second dimension are k_{B} bits, and the redundancy bits of each codeword of the second dimension, namely, parity-B, are (n_{B}−k_{B}) bits. Further, in the example of FIG. 2, CRC (Cyclic Redundancy Check) bits are appended as redundancy bits of the error-detecting code. The CRC bits are included in the information bits both in the first-dimensional encoding and the second-dimensional encoding. Hereinafter, the entire codeword group illustrated in FIG. 2 is referred to as a product codeword.

The product codeword illustrated in FIG. 2 is generated by the following procedure. In order to generate a first-dimensional codeword, the encoder 26 performs error-correction encoding (first encoding) on k_{A}-bit data to thereby generate (n_{A}−k_{A})-bit parity-A. n_{A} is a codeword length of the first-dimensional codeword. Further, in order to generate a second-dimensional codeword, the encoder 26 performs error-correction encoding (second encoding) on k_{B}-bit data to thereby generate (n_{B}−k_{B})-bit parity-B. n_{B} is a codeword length of the second-dimensional codeword. Further, the encoder 26 performs encoding (second encoding) on k_{B}-bit data to thereby generate parity-B. The data encoded by the first encoding and the second encoding is user data received from the host 4 and the CRC bits (redundant bits of CRC) generated based on the user data. It should be noted that data other than the user data received from the host 4, that is, data to be used for control by the memory controller 2, for example, may be the target of the first encoding and the second encoding. As the error-correction code used for the first encoding and the second encoding, a block code such as a BCH code, an RS code, or the like may be used. The error-correction code used for the first encoding and the second encoding may be the same or different.

Further, the encoder 26 encodes (k_{A}×k_{B}−n_{CRC})-bit data by the CRC method to thereby generate CRC bits which are redundant bits. It should be noted that n_{CRC} is the number of bits per product codeword. As illustrated in FIG. 2, the information bits (including the CRC bits) constituting the product codeword constitute the first-dimensional codewords and also the second-dimensional codewords.

The configuration of the codeword illustrated in FIG. 2 is an example, and a codeword to which the decoding method of the present embodiment is applied is not limited to the example of FIG. 2. Further, while n_{A}, n_{B}, k_{A}, and k_{B} are described as the number of bits in the above description, n_{A}, n_{B}, k_{A}, and k_{B} may be the number of symbols. A codeword to which the decoding method of the present embodiment is applicable may be a three or more dimensional product codeword or a code other than a product codeword. Further, while all of the bits of the data are doubly protected with the first dimensional codeword and the second dimensional code in the example of FIG. 2, not all of the bits of the data are necessarily doubly protected. It is only necessary that at least part of the data is doubly protected. Further, while the example of FIG. 2 illustrates an example of using a CRC code as an error-detecting code, a code other than a CRC code may be used as an error-detecting code, or an error-detecting code may not be appended.

While there is no particular constraint regarding the storage location when the product codeword illustrated in FIG. 2 is stored in the non-volatile memory 3, the entire product codeword may be stored on one page, for example, or the first-dimensional codeword may be stored on one page and the entire product codeword may be stored on a plurality of pages. A storage method other than these methods is also applicable.

Next, processing at the time of reading from the non-volatile memory 3 of the present embodiment will be described. When the control unit 23 performs reading from the non-volatile memory 3, the control unit 23 instructs the memory I/F 22 to read while designating an address on the non-volatile memory 3, and also instructs the decoder 27 to start decoding. In accordance with the instruction from the control unit 23, the memory I/F 22 reads a codeword from the non-volatile memory 3. The decoder 27 decodes the codeword read from the non-volatile memory 3.

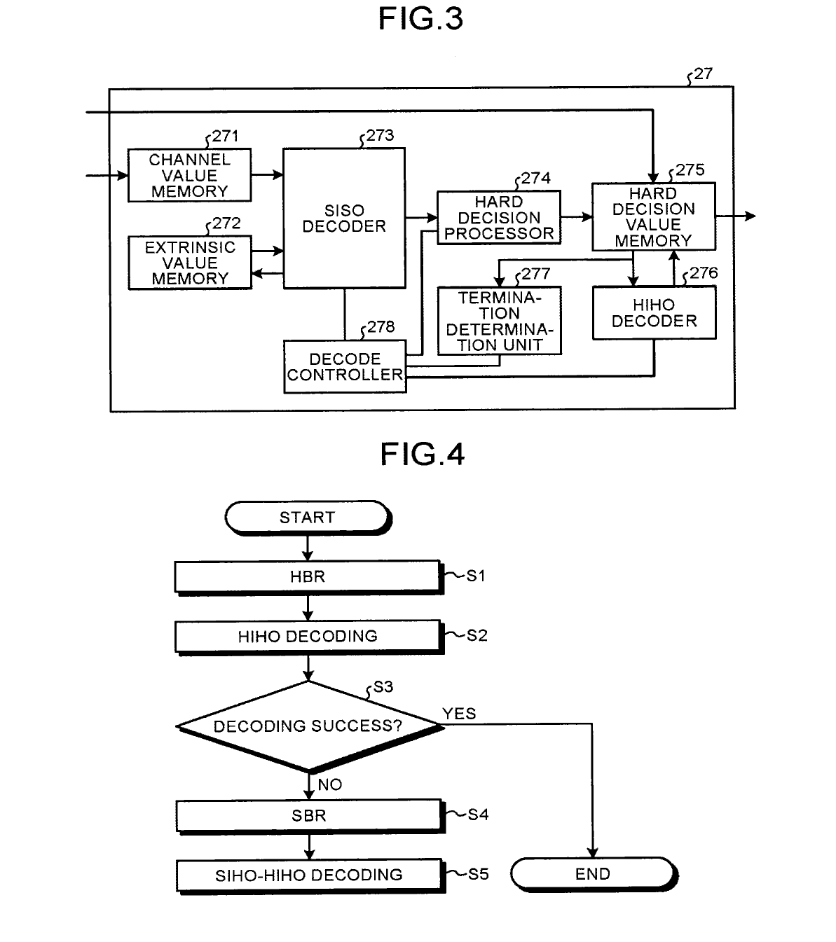

FIG. 3 is a diagram illustrating an exemplary configuration of the decoder 27 of the present embodiment. As illustrated in FIG. 3, the decoder 27 includes a channel value (channel information) memory 271, an extrinsic value (extrinsic information) memory 272, an SISO decoder 273, a hard decision processor 274, a hard decision value memory 275, a HIHO decoder 276, a termination determination unit 277, and a decode controller 278.

The channel value memory 271 is a memory which stores channel information, that is, a received word corresponding to a codeword (data and parity) read as a set of soft decision input values from the non-volatile memory 3. The extrinsic value memory 272 is a memory which stores extrinsic values which are included in the outputs from the SISO decoder 273. The SISO decoder 273 performs SISO decoding on the received word corresponding to the codeword read from the channel value memory 271 to thereby estimate a posteriori values (a posteriori information) to be described below, and output a set of soft decision results including the extrinsic values. The SISO decoder 273 outputs the soft decision result the hard decision processor 274, and stores the extrinsic values in the extrinsic value memory 272.

The hard decision processor 274 performs hard decision on the a posteriori values which are included in the soft decision results output from the SISO decoder 273 to thereby obtain hard decision values, and stores the hard decision values in the hard decision value memory 275. The HIHO decoder 276 performs HIHO decoding on the hard decision values read from the hard decision value memory 275 or on the received word corresponding to the codeword read as a set of hard decision input values from the non-volatile memory 3, and stores the set of hard decision values, which is obtained as the HIHO decoding result, in the hard decision value memory 275. The termination determination unit 277 determines whether or not to terminate decoding using the hard decision values read from the hard decision value memory 275, and notifies the decode controller 278 of the determination result. The decode controller 278 controls the entire operation of the decoder 27.

In the HIHO decoding performed by the HIHO decoder 276, decoding such as bounded distance decoding, for example, is performed on the received word corresponding to the codeword input as a set of hard decision values. HIHO decoding performed by the HIHO decoder 276 is not limited to bounded distance decoding, and any HIHO decoding can be used. In the case of using the product codeword illustrated in FIG. 2, the HIHO decoder 276 first decodes respective first-dimensional codewords constituting the product codeword, sequentially. If there is any codeword in which decoding has not succeeded among the first-dimensional codewords constituting the product codeword, the HIHO decoder 276 corrects the error which could be corrected in the decoding of the first-dimensional codewords, and decodes the second-dimensional codewords. In the decoding of the second-dimensional codewords, if there is any codeword in which decoding has not succeeded, the HIHO decoder 276 corrects the error which could be corrected in the decoding of the second-dimensional codewords, and decodes the first-dimensional codewords again. In this way, processing to repeatedly perform decoding of the first-dimensional codewords and decoding of the second-dimensional codewords, that is, iterative decoding, is performed.

The SISO decoder 273 performs soft decision decoding on the received word corresponding codewords input as soft decision values. While there is no particular constraint on the specific method of soft decision decoding, the principle of soft decision decoding is described in a literature by William Ryan, Shu Lin, Cambridge University Press, “Channel Codes”, 330p-334p (hereinafter referred to as Literature 1), for example. In the present embodiment, based on the premise that the principle described in Literature 1 is used, the definitions of the terms in soft decision decoding such as a channel value, a posteriori value, an extrinsic value, and the like follow the definitions described in Literature 1.

Hereinafter, input and output of the SISO decoder 273 will be described in brief. In soft decision decoding of the SISO decoder 273, received words corresponding to the codewords read by soft bit read from the non-volatile memory 3 serve as inputs of the soft decision decoding. The details of soft bit read will be described below. In soft bit read, a log of a ratio between the probability (or likelihood) that a value stored in a memory cell of the non-volatile memory 3 is zero and the probability (or likelihood) that the value is one, namely an LLR (Log Likelihood Ratio), is obtained. In the present embodiment, a channel value in Literature 1 is an LLR obtained by soft bit read.

Further, if a log of the ratio between the probability that a value stored in the non-volatile memory 3 is zero and the probability that the value being one has been known, it is called a priori information or an a priori value. The SISO decoder 273 uses a channel value, namely LLR, and an a priori value as inputs for each bit in the product codeword to thereby decode the respective codewords of the respective dimensions. This means that the SISO decoder 273 uses a channel value, namely LLR, and an a priori value as inputs to thereby obtain the most likely codeword among the codewords satisfying the code constraints. Through the decoding by the SISO decoder 273, a log of the ratio between the probability that each bit of the codeword is zero and the probability that the each bit is one, that is, a log posteriori probability ratio, is obtained. Hereinafter, the log a posteriori probability ratio is called an a posteriori value.

A resultant of subtracting a channel value (+an a priori value) from an a posteriori value is called an extrinsic value. In the present embodiment, the SISO decoder 273 performs decoding by using extrinsic values obtained in a different dimension as a priori values. For example, the SISO decoder 273 uses extrinsic values obtained based on the a posteriori values obtained by decoding first-dimensional codewords, for decoding of second-dimensional codewords. Further, the SISO decoder 273 is also able to use extrinsic values obtained based on the a posteriori values obtained by decoding second-dimensional codewords, for decoding of first-dimensional codewords. It should be noted that a priori values when starting decoding (if decoding of another dimension has not been performed) are assumed to be given previously.

FIG. 4 is a diagram illustrating an example of reading procedure of the present embodiment. The control unit 23 designates an address to be read and instructs the memory I/F 22 to read it by hard bit read (HBR) from the non-volatile memory 3, and the memory I/F 22 performs hard bit read (step S1). Hard bit read is a reading method in which each of the bits constituting a codeword is read as a hard decision value of zero or one. The read codeword (the set of hard decision values) is stored in the hard decision value memory 275.

If the non-volatile memory 3 is a NAND memory, at the time of data writing, electrons are injected such that the number of electrons (charge amount) of a floating gate corresponds to any of distributions (threshold distributions), according to the data value. In this example, in order to simplify the description, description will be given on an example of one bit/cell in which one memory cell stores one bit. In the case of one bit/cell, either one of two distributions corresponds to “zero”, and the other corresponds to “one”. In the case of applying a voltage to a memory cell, if a voltage not less than a voltage value corresponding to the charge amount of the memory cell is applied, an electric current flows, while if a voltage less than the voltage is applied, an electric current does not flow. Accordingly, the voltage serving as the boundary is determined for each memory cell corresponding to the charge amount of the memory cell. The voltage determined corresponding to the charge amount of the memory cell is called a threshold voltage (Vth) herein. By injecting charges so as to correspond to one of two threshold distributions in the initial state, and applying a reference read voltage for separating the two threshold distributions at the time of reading, it is possible to determine whether or not the data stored in the memory cell is one.

Hard bit read is reading in which the non-volatile memory 3 applies a reference read voltage to a memory cell, determines whether the data stored in the memory cell is one or zero, and outputs the determined result. It should be noted that the read voltage to be applied at the time of hard bit read may be changed from the reference read voltage.

Going back to the description of FIG. 4, the control unit 23 instructs the decoder 27 to perform HIHO decoding, and the decoder 27 performs HIHO decoding (step S2). Specifically, the decoder 278 instructs the HIHO decoder 276 to perform HIHO decoding, and the HIHO decoder 276 performs decoding using the hard decision values read from the hard decision value memory 275. The HIHO decoder 276 notifies, for each codeword, the decode controller 278 of whether or not the decoding succeeded (error correction succeeded).

The decode controller 278 determines whether or not decoding of all of the codewords constituting the product codeword succeeded based on the notification from the HIHO decoder 276, and notifies the control unit 23 of the determination result. The control unit 23 determines whether or not decoding of all of the codewords constituting the product codeword succeeded based on the notification from the decode controller 278 (step S3), and if decoding of all of the codewords succeeded (step S3, Yes), ends the reading. It should be noted that at step S3, the control unit 23 determines whether or not decoding of all of the codewords of at least one dimension, constituting the product codeword, succeeded. Further, if redundant bits are appended to the error-detecting code such as CRC, it is also possible to perform checking with use of the error-detecting code together, when determining whether or not decoding succeeded at step S3.

If determining that there is a failed one in decoding among the codewords constituting the product codeword (step S3, No), the control unit 23 designates a read address and instructs the memory I/F 22 to read the received word corresponding to the produce codeword by soft bit read (SBR) from the non-volatile memory 3, and the memory I/F 22 performs soft bit read which is reading to read it as a set of soft decision values (step S4).

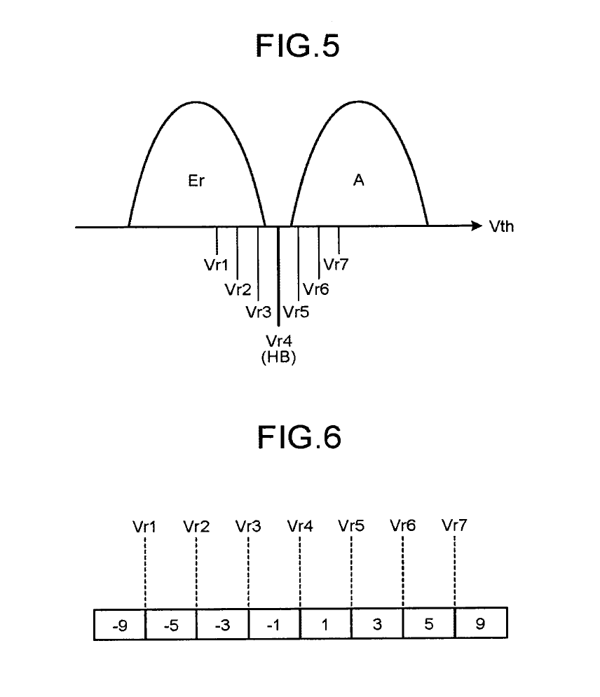

FIG. 5 is a diagram for explaining soft bit read. The horizontal axis of FIG. 5 shows a threshold voltage, and the vertical axis shows frequency. FIG. 5 illustrates an example of a single level cell which stores one bit/cell. Er (erase) distribution on the left side corresponds to a data value “one”, and A distribution on the right side corresponds to a data value “zero”. In soft bit read, in addition to a reference read voltage to be used in hard bit read, reading is performed by using a plurality of read voltages on both sides of the reference read voltage. In the example of FIG. 5, an example in which soft bit read is performed using seven read voltages in total is illustrated. A read voltage described as Vr4 (HB) shows a reference read voltage to be used in hard bit read. In soft bit read, reading is performed by using seven read voltages in total, that is, Vr4, and Vr1, Vr2, and Vr3 which are lower than Vr4, and Vr5, Vr6, and Vr7 which are higher than Vr4. It should be noted that the number of read voltages in soft bit read is not limited to seven.

Then, by using the LLR table, for example, it is possible to obtain an LLR from the determination result of whether or not the threshold voltage of each memory cell is not lower than each reading voltage. FIG. 6 is a diagram illustrating an exemplary LLR table. For example, if the threshold voltage of a memory cell is determined to be less than Vr1, the LLR is minus nine, while if the threshold voltage of a memory cell is determined to be not less than Vr1 and less than Vr2, the LLR is minus five. FIG. 6 illustrates an example, and the LLR table is not limited the example of FIG. 6. Further, it is also possible to obtain the LLR using a formula for computation, without using the LLR table, for example. In the present embodiment, a process from performing soft bit read until conversion to an LLR is called a process of reading data from the non-volatile memory 3 as a soft decision values.

Conversion to LLR from the determination result of whether or not the threshold value of each memory cell is not less than each read voltage may be performed by the memory controller 2 or by the non-volatile memory 3. In the case where the memory controller 2 performs it, the non-volatile memory 3 outputs, for each memory cell, information representing whether or not the threshold voltage is in any of eight areas, namely, less than Vr1, not less than Vr1 but less than Vr2, not less that Vr2 but less than Vr3, not less than Vr3 but less than Vr4, not less than Vr4 but less than Vr5, not less than Vr5 but less than Vr6, not less than Vr6 but less than Vr7, and not less than Vr7, for example. Then, the memory I/F 22 obtains an LLR based on the LLR table and the information output from the non-volatile memory 3, and stores it in the channel value memory 271 of the decoder 27.

It should be noted that while FIGS. 5 and 6 describe an example of a single level cell which stores one bit/cell, even in the case of a multilevel cell, reading is performed using a plurality of reading voltages for each boundary of threshold distributions, which is similar to the example of a single level sell. Then, an LLR is calculated based on the reading results using a plurality of reading voltages.

Going back to the description of FIG. 4, the control unit 23 instructs the decoder 27 to perform SISO-HIHO decoding which is combined decoding of SISO decoding and HIHO decoding, and the decoder 27 performs SISO-HIHO decoding (step S5). SISO-HIHO decoding will be described below.

By performing the processing described above, if error correction can be made in hard bit read and HIHO decoding, decoding ends by performing hard bit read and HIHO decoding, and high-speed reading can be performed. On the other hand, if error correction cannot be made in hard bit read and HIHO decoding, SISO decoding having higher correction performance is performed. In the case of decoding the product codeword exemplary illustrated in FIG. 2 only by SISO decoding, it is considered to use a method of repeating decoding of first-dimensional codewords and decoding of second-dimensional codewords in such a manner as to decode first-dimensional codewords and based on the a posteriori values obtained by the decoding of the first-dimensional codewords, decode second-dimensional codewords, and based on the a posteriori values obtained by the decoding of the second-dimensional codewords, perform decoding of first-dimensional codewords again, until the termination condition is satisfied. However, in this method, SISO decoding takes a longer processing time compared with HIHO decoding, and if the number of iterations of SISO decoding becomes large, the processing time of SISO decoding becomes extremely long.

As such, in the present embodiment, if error correction cannot be made in hard bit read and HIHO decoding, SISO-HIHO decoding, which is a combined decoding of SISO decoding and HIHO decoding, is performed. It should be noted that in the present embodiment, hard bit read and HIHO decoding are performed first, and only when error correction cannot be made in hard bit read and HIHO decoding, soft bit read and SISO-HIHO decoding are performed. However, it is possible to perform soft bit read and SISO-HIHO decoding from the beginning, without performing hard bit read and HIHO decoding.

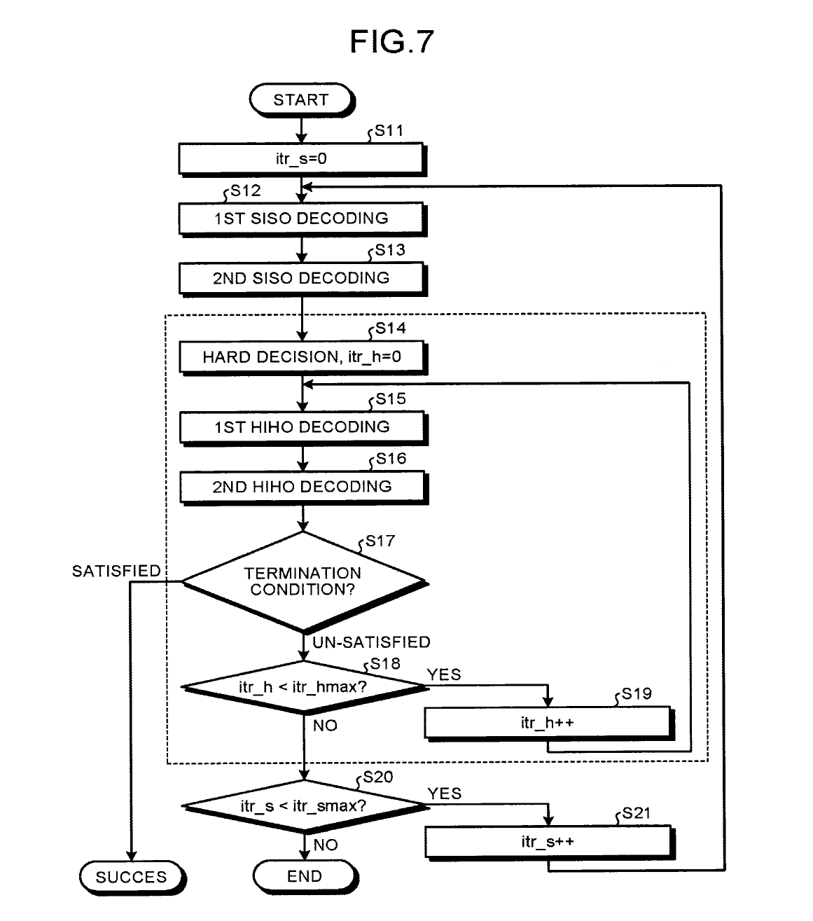

Next, SISO-HIHO decoding of the present embodiment will be described. FIG. 7 is a flowchart illustrating an exemplary procedure of SISO-HIHO decoding of the present embodiment. First, when the decode controller 278 is instructed to start SISO-HIHO processing by the control unit 23, the decode controller 278 initializes the counter itr_s of the number of iterations of SISO decoding to zero (step S11). Then, the decoder 27 performs first SISO decoding on a first-dimensional codeword group constituting the product codeword (step S12). More specifically, the following processing will be performed. The decode controller 278 instructs the SISO decoder 273 to perform SISO decoding, and when the SISO decoder 273 receives the instruction from the decode controller 278, the SISO decoder 273 reads an LLR corresponding to each bit of each first-dimensional codeword constituting the product codeword from the channel value memory 271. Further, the SISO decoder 273 reads an extrinsic value, obtained as a result of second-dimensional SISO decoding, corresponding to each bit of each first-dimensional codeword, from the extrinsic value memory 272, and uses it as an input to the first SISO decoding as an a priori value for each bit in each codeword of the first dimension. However, at the time of initial first SISO decoding of iterative processing, a predetermined value (for example, zero) is used as an a priori value. Then, the SISO decoder 273 performs SISO decoding on each codeword using the LLRs and the a priori values, and stores the extrinsic values obtained by the SISO decoding in the extrinsic value memory 272.

Next, the decoder 27 performs second SISO decoding on a second-dimensional codeword group constituting the product codeword (step S13). More specifically, the decoder 27 performs the following processing. The SISO decoder 273 reads an LLR corresponding to each bit of each second-dimensional codeword constituting the product codeword, from the channel value memory 271. Further, the SISO decoder 273 reads the extrinsic value obtained as a result of first-dimensional SISO decoding (step S12), corresponding to each bit of each second-dimensional codeword, from the extrinsic value memory 272, and uses it as an input to the second SISO decoding as an a priori value of the second dimension. Then, the SISO decoder 273 performs SISO decoding on each codeword using the LLRs and the a priori values, and stores the extrinsic values, obtained by the SISO decoding, in the extrinsic value memory 272. Further, the SISO decoder 273 outputs the a posteriori value of each bit of each codeword obtained by the second SISO decoding, to the hard decision processor 274.

The hard decision processor 274 performs hard decision on the a posteriori value of each bit of each codeword, and stores the hard decision result in the hard decision value memory 275. Further, the decode controller 278 initializes the counter itr_h of the number of iterations of HIHO decoding to zero (step S14). The decode controller 278 instructs the HIHO decoder 276 to perform HIHO decoding, and when the HIHO decoder 276 receives the instruction from the decode controller 278, the HIHO decoder 276 performs first HIHO decoding on the first-dimensional codeword group constituting the product codeword (step S15). Specifically, the following processing will be performed. The HIHO decoder 276 reads a hard decision value corresponding to each bit of each first-dimensional codeword from the hard decision value memory 275, and performs bounded distance decoding, for example, as first HIHO decoding. If data which should be corrected is found on the hard decision value memory 275 by the first HIHO decoding, the HIHO decoder 276 updates the corresponding data to a correct value.

Next, the HIHO decoder 276 performs second HIHO decoding on the second-dimensional codeword group constituting the product codeword (step S16). Specifically, the HIHO decoder 276 reads a hard decision value corresponding to each bit of each second-dimensional codeword, from the hard decision value memory 275, and performs bounded distance decoding, for example, as second HIHO decoding. If data which should be corrected is found on the hard decision value memory 275 by the second HIHO decoding, the HIHO decoder 276 updates the corresponding data to a new value.

Next, the termination determination unit 277 determines whether or not the termination determination condition is satisfied (step S17). The decode controller 278 outputs the hard decision values stored in the hard decision value memory 275 as read data after the error correction. The termination determination unit 277 notifies the decode controller 278 of a determination result of whether or not the termination determination condition is satisfied. As the termination determination condition, if redundant bits of an error-detecting code such as CRC are appended, check of the error-detecting code is satisfied (no error), parity check of the first-dimensional codeword is satisfied (no error), parity check of the second-dimensional codeword is satisfied (no error), or a combination of two or more of these checks, may be used, for example. In the case of using the product codeword of FIG. 2, as CRC are appended, a condition that the CRC is satisfied may be used as a termination condition.

If it is determined by the termination determination unit 277 that the termination determination condition is satisfied (step S17, satisfied), the SISO-HIHO decoding is terminated in successful decoding. If it is determined that the termination determination condition is not satisfied (step S17, un-satisfied), the decode controller 278 determines whether or not the counter itr_h of the number of iterations of HIHO decoding is less than the maximum number of iterations itr_hmax (step S18). If itr_h is less than itr_hmax (step S18, Yes), the decode controller 278 increments itr_h by one (step S19), and returns to step S15.

When itr_h becomes equal to itr_hmax (step S18, No), the decode controller 278 determines whether or not the counter itr_s of the number of iterations of SISO decoding is less than the maximum number of iterations itr_smax of SISO decoding (step S20). If itr_s is less than itr_smax (step S20, Yes), the decode controller 278 increments itr_s by one (step S21), and returns to step S12. At this time, the decode controller 278 may perform processing to reflect the result of HIHO decoding on SISO decoding. In the case of performing processing to reflect the result of HIHO decoding on SISO decoding, any processing method may be used. For example, in order that the amplitude of the a posteriori value of the bit corrected by the HIHO decoding becomes smaller, an extrinsic value (an extrinsic value other than the extrinsic value of the second dimension used in SISO decoding) is adjusted, and is input to the SISO decoder 273. When itr_s becomes equal to itr_smax (step S20, No), SISO-HIHO decoding is terminated in failure.

The part surrounded by the dotted line in FIG. 7 illustrates iterative processing of HIHO decoding, that is, iterative HIHO decoding. In the present embodiment, one time of processing of SISO decoding (processing up to incrementing itr_s by one) includes iterative processing of HIHO decoding, as illustrated in FIG. 7. HIHO decoding can be performed in a much shorter calculation time, compared with that of SISO decoding. As such, there is a case where the required processing time can be shorter by repeating HIHO decoding a plurality of times, than performing SISO decoding once, to correct a similar number of bit errors. Accordingly, the present embodiment is able to reduce the processing time, compared with a method of repeating only SISO decoding.

### Second Embodiment

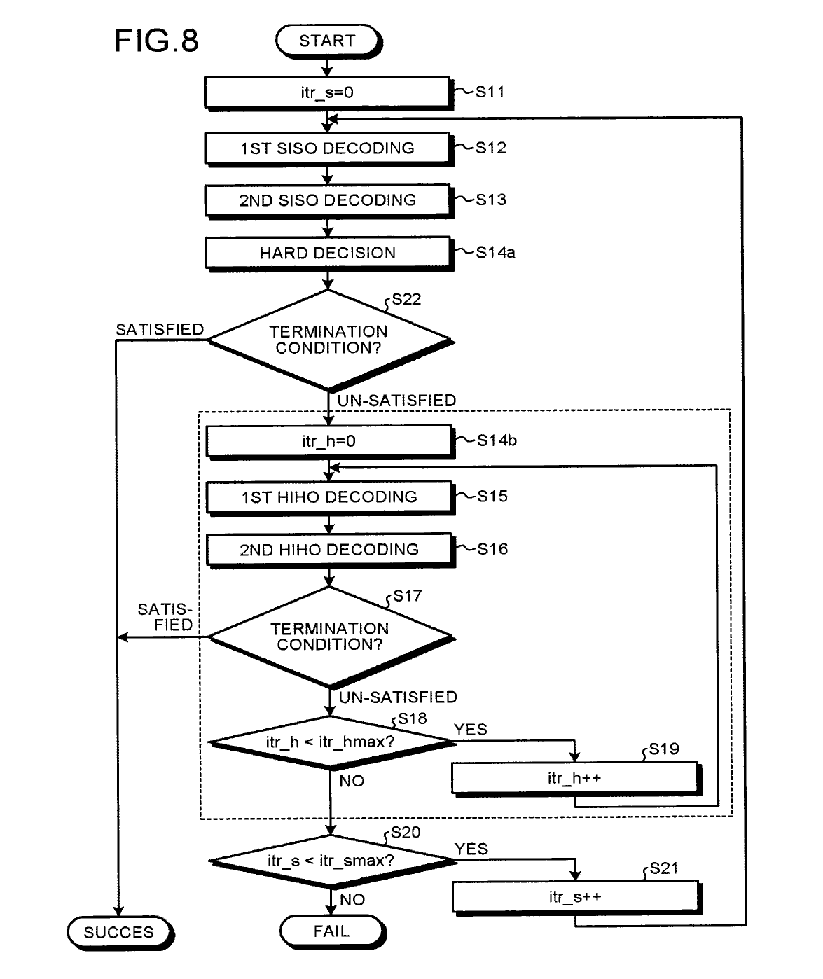

FIG. 8 is a flowchart illustrating an example of SISO-HIHO decoding procedure in a storage device according to a second embodiment. The configuration of the storage device of the present embodiment is similar to that of the storage device of the first embodiment. Hereinafter, description will be given on the part different from the first embodiment.

Writing operation (including encoding) to the non-volatile memory 3 of the present embodiment is similar to that of the first embodiment. The entire reading operation from the non-volatile memory 3 in the present embodiment is similar to that illustrated in FIG. 4 of the first embodiment. In the present embodiment, in SISO-HIHO decoding at step S5 in FIG. 4, the processing illustrated in FIG. 8 is performed instead of the processing illustrated in FIG. 7.

Next, SISO-HIHO decoding of the present embodiment will be described. Step S11 to step S13 are the same as those of the first embodiment. Subsequent to step S13, the hard decision processor 274 performs hard decision on the a posteriori value of each bit of each codeword, and stores the hard decision result in the hard decision value memory 275 (step S14a). The termination determination unit 277 determines whether or not the termination determination condition is satisfied (step S22). The termination determination condition is the same as that of the first embodiment. At step S22, if an error-detecting code such as CRC are used, the termination determination unit 277 determines whether or not there is an error by using the hard decision values obtained by performing hard decision on the a posteriori values and stored in the hard decision value memory 275.

If it is determined by the termination determination unit 277 that the termination determination condition is satisfied (step S22, satisfied), the SISO-HIHO decoding is terminated in successful decoding. If it is determined that the termination determination condition is not satisfied (step S22, un-satisfied), the decode controller 278 initializes the counter itr_h of the number of iterations of HIHO decoding to zero (step S14b). Then, step S15 to step S21 are the same as those of the first embodiment.

Further, with respect to SISO-HIHO decoding of the first embodiment, it is possible to add determination of whether or not the termination determination condition is satisfied, between step S15 and step S16. If the termination determination condition is satisfied, SISO-HIHO decoding is terminated because correction was performed correctly, while if the termination determination condition is not satisfied, the processing proceeds to S16.

Further, with respect to SISO-HIHO decoding of the first embodiment, it is possible to add determination of whether or not the termination determination condition is satisfied, between step S12 and step S13. If checking using an error-detecting code is used as the termination determination condition, after the first SISO decoding at step S12, the hard decision processor 274 performs hard decision on the a posteriori value of each bit of each codeword, and stores the hard decision result in the hard decision value memory 275. With use of the hard decision result, determination of whether or not the termination determination condition is satisfied is performed. Then, if the termination determination condition is satisfied, SISO-HIHO decoding is terminated because correction was performed correctly, while if the termination determination condition is not satisfied, the processing proceeds to S13.

Any two or more items of the determination of the termination determination condition described above may be added to SISO-HIHO decoding of the first embodiment.

As described above, in the present embodiment, the part of determining whether or not the termination determination condition is satisfied is added to the first embodiment. As such, if the termination determination condition is satisfied, it is possible to terminate the processing promptly, whereby the processing time required for decoding can be reduced.

### Third Embodiment

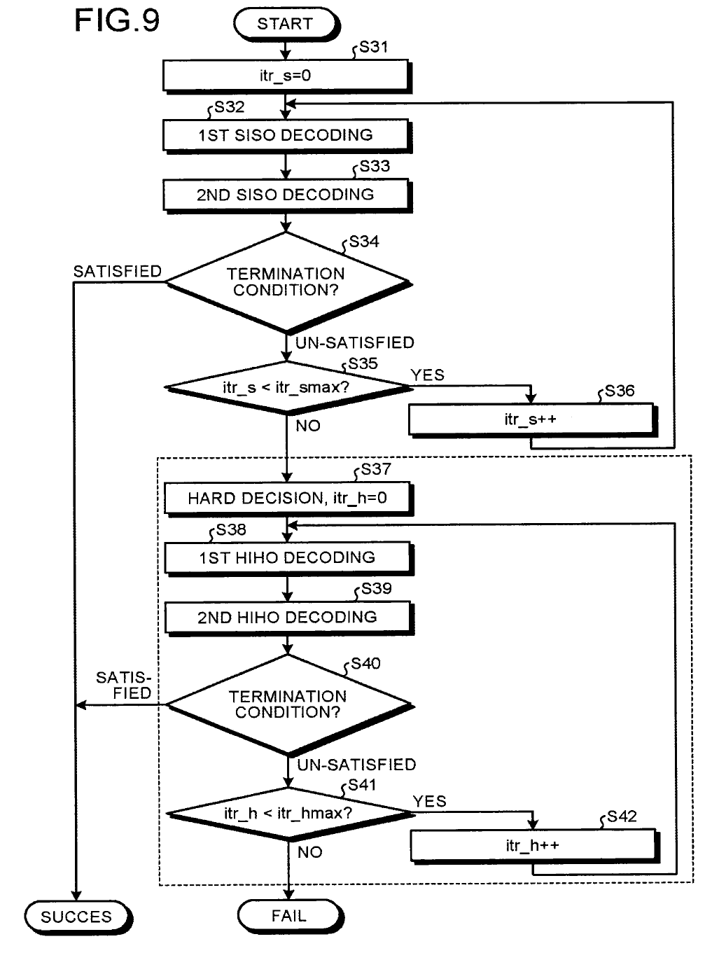

FIG. 9 is flowchart illustrating an example of SISO-HIHO decoding procedure in a storage device according to a third embodiment. The configuration of the storage device of the present embodiment is similar to that of the storage device of the first embodiment. Hereinafter, description will be given on the part different from the first embodiment.

First, step S31 to step S33 are performed in the same manner as step S11 to step S13 of the first embodiment. After the second SISO decoding at step S33, the termination determination unit 277 determines whether or not the termination determination condition is satisfied (step S34). The termination determination condition is the same as that of the first embodiment. If checking using an error-detecting code is used as the termination determination condition, after step S33, the hard decision processor 274 performs hard decision on the a posteriori value of each bit of each codeword, and stores the hard decision result in the hard decision value memory 275. At step S34, determination of whether or not the termination determination condition is performed using the hard decision result.

If it is determined by the termination determination unit 277 that the termination determination condition is satisfied (step S34, satisfied), the decode controller 278 terminates the SISO-HIHO decoding in successful decoding. If it is determined that the termination determination condition is not satisfied (step S34, un-satisfied), the decode controller 278 determines whether or not the counter itr_s of the number of iterations of SISO decoding is less than the maximum number of iterations itr_smax of the SISO decoding (step S35). If itr_s is less than itr_smax (step S35, Yes), the decode controller 278 increments itr_s by one (step S36), and returns to step S32.

When itr_s becomes equal to itr_smax (step S35, No), the processing proceeds to step S37. Step S37 to step S42 are similar to step S14 to step S19 in the first embodiment. However, at step S41, when itr_h becomes equal to itr_hmax (step S41, No), SISO-HIHO decoding is terminated in failure. Further, if checking using an error-detecting code is used as the termination determination condition, after step S33, as the hard decision result has been stored in the hard decision value memory 275, it is not necessary to perform hard decision of the a posteriori value at step S37.

Further, similar to the second embodiment, it is possible to add determination of whether or not the termination determination condition is satisfied in one or more of between step 32 and step S33 and between step S38 and step S39.

As described above, in the present embodiment, SISO decoding is iterated the maximum number of iterations, and only when an error cannot be corrected completely, HIHO decoding is performed. As such, there is a case where the processing time is reduced compared with the case of performing SISO decoding only, depending on the error occurrence state.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller comprising a decoder, the decoder including:
a SISO decoder that performs SISO decoding based on a codeword read out as a set of soft decision values, the codeword being stored in a non-volatile memory, and outputs a posteriori information;
a hard decision processor that performs hard decision on the a posteriori information and calculates a set of hard decision values; and
a HIHO decoder that performs HIHO decoding by using the hard decision values.

2. The memory controller according to claim 1, wherein
the decoder includes a termination determination unit that determines whether or not to terminate SISO-HIHO decoding including the SISO decoding and HIHO decoding, and
the decoder performs iterative HIHO decoding in which the HIHO decoding is iterated until the termination determination unit determines to terminate the SISO-HIHO decoding or until the number of iterations becomes a first maximum number of iterations.

3. The memory controller according to claim 2, wherein
the termination determination unit terminates the SISO-HIHO decoding if the termination determination unit determines that the HIHO decoding succeed.

4. The memory controller according to claim 2, wherein
the codeword includes information bits including error detection redundant bits, and
the termination determination unit determines whether or not to terminate the SISO-HIHO decoding with use of the error detection redundant bits of the codeword after the HIHO decoding.

5. The memory controller according to claim 2, wherein
if the termination determination unit determines not to terminate the SISO-HIHO decoding after the decoder has iterated the HIHO decoding until the number of iterations becomes the first maximum number of iterations, the decoder performs processing including the SISO decoding, the calculation of the hard decision value, and the iterative HIHO decoding, and
the decoder iterates the processing until the termination determination unit determines to terminate the SISO-HIHO decoding or until the number of iterations of the processing becomes a second maximum number of iterations.

6. The memory controller according to claim 5, wherein
the SISO decoding in the processing uses a decoding result of the iterative HIHO decoding.

7. The memory controller according to claim 5, wherein
the codeword includes information bits including error detection redundant bits, and
the termination determination unit determines whether or not to terminate the SISO-HIHO decoding with use of the error detection redundant bits of the hard decision values of the codeword calculated by the hard decision processor.

8. The memory controller according to claim 1, wherein
the codeword is a group of first-dimensional codewords and/or second-dimensional codewords forming a product codeword, and
the SISO decoder calculates extrinsic information with use of the a posteriori information of the first-dimensional codewords, and uses the extrinsic information as a priori information in estimating a posteriori information of the second-dimensional codewords.

9. The memory controller according to claim 8, wherein
the SISO decoder performs SISO decoding of the second-dimensional codewords after performing SISO decoding of the first-dimensional codewords, and
the termination determination unit determines whether or not to terminate the SISO decoding based on a set of hard decision values corresponding to the a posteriori information obtained by the SISO decoding of the first-dimensional codewords.

10. The memory controller according to claim 8, wherein
the HIHO decoder performs HIHO decoding of the second-dimensional codewords after performing HIHO decoding of the first-dimensional codewords, and
the termination determination unit determines whether or not to terminate the HIHO decoding based on the codewords obtained by the HIHO decoding of the first-dimensional codewords.

11. The memory controller according to claim 1, wherein
the HIHO decoder performs HIHO decoding on the codeword read out as a set of hard decision values from the non-volatile memory, and
the SISO decoder, when the HIHO decoding of the read codeword failed, reads the codeword as a set of soft decision values from the non-volatile memory and performs the SISO decoding based on the read soft decision values.

12. A storage device comprising:
a non-volatile memory in which a codeword is stored;
a SISO decoder that performs SISO decoding based on the codeword read out as a set of soft decision values from the non-volatile memory, and outputs a posteriori information;
a hard decision processor that performs hard decision on the a posteriori information and calculates a set of hard decision values; and
a HIHO decoder that performs HIHO decoding by using the hard decision values.

13. A method of controlling a non-volatile memory in which a codeword is stored, the method comprising:
performing SISO decoding based on the codeword read out as a set of soft decision values from the non-volatile memory, and outputting a posteriori information;
performing hard decision on the a posteriori information and calculating a set of hard decision values of the codeword; and
performing HIHO decoding by using the hard decision values.

14. The method according to claim 13, further comprising:
performing termination determination, by a termination determination unit, to determine whether or not to terminate SISO-HIHO decoding including the SISO decoding and HIHO decoding; and
performing iterative HIHO decoding in which the HIHO decoding is iterated until it is determined to terminate the SISO-HIHO decoding by the termination determination or until the number of iterations becomes a first maximum number of iterations.

15. The method according to claim 14, wherein the termination determination unit terminates the SISO-HIHO decoding if the termination determination determines that the HIHO decoding succeed.

16. The method according to claim 15, wherein
the codeword includes information bits including error detection redundant bits, and
the termination determination unit determines whether or not to terminate the SISO-HIHO decoding with use of the error detection redundant bits of the codeword after the HIHO decoding.

17. The method according to claim 14, further comprising:
if the termination determination unit determines not to terminate the SISO-HIHO decoding after iterating the HIHO decoding until the number of iterations becomes the first maximum number of iterations, performing processing including the SISO decoding, the calculation of the hard decision values, and the iterative HIHO decoding; and
iterating the processing until the termination determination unit determines to terminate the SISO-HIHO decoding or until the number of iterations of the processing becomes a second maximum number of iterations.

18. The method according to claim 17, wherein
the codeword includes information bits including error detection redundant bits, and
the termination determination unit determines whether or not to terminate the SISO-HIHO decoding with use of the error detection redundant bits of the hard decision values of the codeword calculated using the a posteriori information.

19. The method according to claim 13, wherein
the codeword is a group of first-dimensional codewords and/or second-dimensional codewords forming a product codeword, and
the SISO decoding includes calculating extrinsic information with use of the a posteriori information of the first-dimensional codewords, and using the extrinsic information as a priori information in estimating the a posteriori information of the second-dimensional codewords.

20. The method according to claim 19, wherein
the SISO decoding includes performing SISO decoding of the second-dimensional codewords after performing SISO decoding of the first-dimensional codewords, and
whether or not to terminate the SISO decoding is determined based on a hard decision values corresponding to the a posteriori information obtained by the SISO decoding of the first-dimensional codewords.
